(19) United States
(12) Patent Application Publication
(10) Pub. No.: US 2024/0268066 A1
(43) Pub. Date: Aug. 8, 2024

(54) METHOD FOR CONTROLLING FAN AND HEAT DISSIPATION DEVICE

(71) Applicant: Fulian Precision Electronics (Tianjin) Co., LTD., Tianjin (CN)

(72) Inventor: TSUNG-MING CHEN, New Taipei (TW)

(21) Appl. No.: 18/135,507

(22) Filed: Apr. 17, 2023

(30) Foreign Application Priority Data
Feb. 7, 2023 (CN) 202310085349.9

(51) Int. Cl. H05K 7/20; G06F 1/20

(52) U.S. Cl. CPC H05K 7/20209; G06F 1/20; H05K 7/20172

(57) ABSTRACT

A method for controlling fan and a heat dissipation device are provided, the heat dissipation device includes a plurality of dual-rotor fans and a boost unit. Each dual-rotor fan includes two rotor units. A first end of the boost unit is connected to the rotor units of the dual-rotor fans, a second end is connected to a power supply terminal. The heat dissipation device determines if the dual-rotor fan with one of the rotor units fails to be a target fan; controls the boost unit to increase a voltage of a power supply of the power supply terminal to a first predetermined voltage value, to output the power supply to a normal one of the rotor units of the target fan.

### CROSS-REFERENCE TO RELATED APPLICATIONS

This application claims priority to Chinese Patent Application No. 202310085349.9 filed on Feb. 7, 2023, in China National Intellectual Property Administration, the contents of which are incorporated by reference herein.

### FIELD

The subject matter herein generally relates to computer heat dissipation technologies, and specially relates to a method for controlling fan and a heat dissipation device.

### BACKGROUND

Fan with dual-rotor is widely applied in mainframe computer equipment, a plurality of fans with dual-rotor may form heat dissipation device for the mainframe computer equipment. The heat dissipation device may be controlled by a computer equipment system or a control unit thereof.

In a related art, when one of the rotor units of the dual-rotor fan fails, the control system will keep the other rotor unit of the dual-rotor fan in operation, so that the dual-rotor fan can output some air flow. However, as time goes by, since the insufficient air flow of the dual-rotor fan caused by the faulty rotor units, heat accumulation may occur in corresponding areas of the computer equipment, thereby affecting normal operations of the computer equipment.

### BRIEF DESCRIPTION OF THE DRAWINGS

Implementations of the present disclosure will now be described, by way of example only, with reference to the attached figures.

FIG. 1 is a schematic diagram of at least one embodiment of a heat dissipation device according to the present disclosure.

FIG. 2 is a flow chart of one embodiment of a method for controlling fan according to the present disclosure.

FIG. 3 is a flow chart of another embodiment of a method for controlling fan according to the present disclosure.

FIG. 4 is a flow chart of one embodiment of a method for determined target fan according to the present disclosure.

FIG. 5 is a schematic diagram of one embodiment of a first kind of a heat dissipation device according to the present disclosure.

FIG. 6 is a schematic diagram of one embodiment of a second kind of a heat dissipation device according to the present disclosure.

FIG. 7 is a schematic diagram of one embodiment of a third kind of a heat dissipation device according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts have been exaggerated to better show details and features of the present disclosure.

Several definitions that apply throughout this disclosure will now be presented.

The term “coupled” is defined as connected, whether directly or indirectly through intervening components, and is not necessarily limited to physical connections. The connection may be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but may have one or more deviations from a true cylinder. The term “comprising,” when utilized, means “including, but not necessarily limited to”; it specifically indicates open-ended inclusion or membership in the so-described combination, group, series, and the like.

The present disclosure is described in relation to a method for controlling fan and a heat dissipation device, for solving a problem of insufficient air flow of a dual-rotor fan where one of the rotor units fails, so as to avoid heat accumulation in corresponding areas of a computer equipment, so that the computer equipment can operate normally.

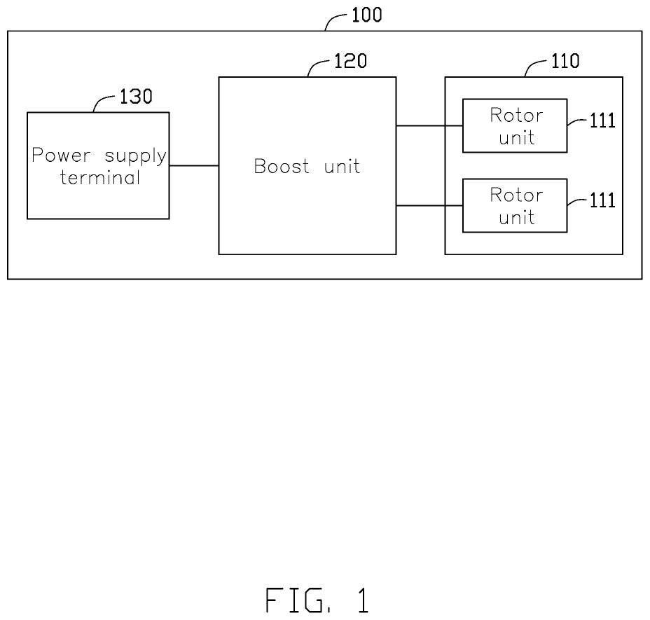

FIG. 1 illustrates a schematic diagram of at least one embodiment of a heat dissipation device 100 applied in a computer equipment for providing air flow to dissipate heat from the computer equipment. The heat dissipation device 100 includes a plurality of dual-rotor fans 110. Each dual-rotor fan 110 includes two rotor units 111 and a boost unit 120. A first end of the boost unit 120 is connected to the rotor units 111, a second end of the boost unit 120 is connected to a power supply terminal 130.

The computer equipment includes computers and large-scale servers, etc., and the dual-rotor fans 110 can be arranged in the area where the computer equipment needs to dissipate heat, or on various heating components according to requirements. The power supply terminal 130 may be a system power supply terminal of the computer equipment, or an independent power supply terminal of the heat dissipation device 100, which is not limited by the present disclosure.

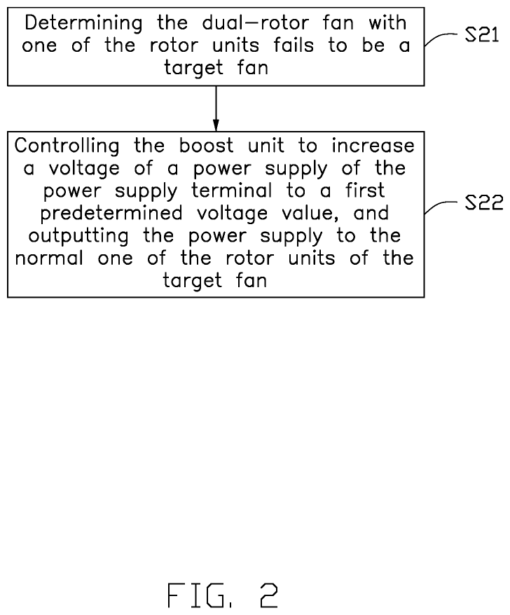

Referring to FIG. 2, a flow chart of a method for controlling fan according to at least one embodiment of the present disclosure is provided. The method includes:

At block S21, determining the dual-rotor fan with one of the rotor units fails to be a target fan.

In at least one embodiment, after the dual-rotor fans start, air flow generated by the dual-rotor fans can dissipate heat from the computer equipment, the controlling system can detect a working state of the dual-rotor fan in real time, when one of the rotor units of the dual-rotor fan being abnormal is detected, determining the dual-rotor fan with one of the rotor units fails to be the target fan.

The working state of the dual-rotor fan can be detected by detecting a working current of the dual-rotor fan. For instance, one of the rotor units of the dual-rotor fan can be controlled to work, and a current value of the dual-rotor fan can be detected and recorded as a predetermined current value. When detecting the working state of the dual-rotor fan in real time, the real-time working current is detected and compared with the predetermined current value. When the real-time working current being smaller than the predetermined current value is determined, one of the rotor units of the dual-rotor fan fails can be determined.

Or, the working state can be detected by detecting a working voltage of the dual-rotor fan. For instance, one of the rotor units of the dual-rotor fan can be controlled to work, and a current voltage value of the dual-rotor fan can be detected and recorded as a predetermined voltage value. When detecting the working state of the dual-rotor fan in real time, the real-time working voltage is detected and compared with the predetermined voltage value. When the real-time working voltage being smaller than the predetermined voltage value is determined, one of the rotor units of the dual-rotor fan fails can be determined.

At block S22, controlling the boost unit to increase a voltage of a power supply of the power supply terminal to a first predetermined voltage value, and outputting the power supply to the normal one of the rotor units of the target fan.

In at least one embodiment, the boost unit includes a charge pump and a boost circuit for increasing voltages. The power supply terminal may be a system power supply terminal of the computer equipment, the rotor units of the dual-rotor fans may be connected to the power supply terminal by cables. The rotor units of the dual-rotor fans can receive the power supply from the power supply terminal through cables when in the normal working state.

The boost unit can be arranged on a first cable that connected between the rotor units of the dual-rotor fans and the power supply terminal. When the rotor units of the dual-rotor fan work normally, the boost unit can sever as a part of the first cable, which is configured to conduct the power supply but not increasing voltages. When one of the rotor units of the dual-rotor fan fails, the boost unit starts and increases the voltage that transmitted from the first cable to the rotor units to the first predetermined voltage value, so as to increase a working speed of the rest of the rotor units of the dual-rotor fans.

Or, the boost unit can be arranged on a second cable that connected between the rotor units of the dual-rotor fans and the power supply terminal. When the rotor units of the dual-rotor fans work normally, the boost unit can sever as a switch, which switches off the connection between the rotor units of the dual-rotor fans and the power supply terminal by the second cable, the rotor units of the dual-rotor fans can receive the power supply from the power supply terminal through the first cable. When one of the rotor units of the dual-rotor fan fails, the first cable can be switched off, the boost unit starts and increases the voltage that transmitted from the second cable to the rotor units to the first predetermined voltage value, so as to increase the working speed of the rest of the rotor units of the dual-rotor fans.

In at least one embodiment, when one of the rotor units of the dual-rotor fan fails, the boost unit can increase the input voltage of the normal one of the rotor units of the dual-rotor fan, to increase the working speed of the normal one of the rotor units of the dual-rotor fan, so as to ensure the air flow generated by the dual-rotor fan with one of the rotor units failing, heat accumulation in corresponding areas of the computer equipment can be prevented, thereby the normal operation of the computer equipment can be ensured.

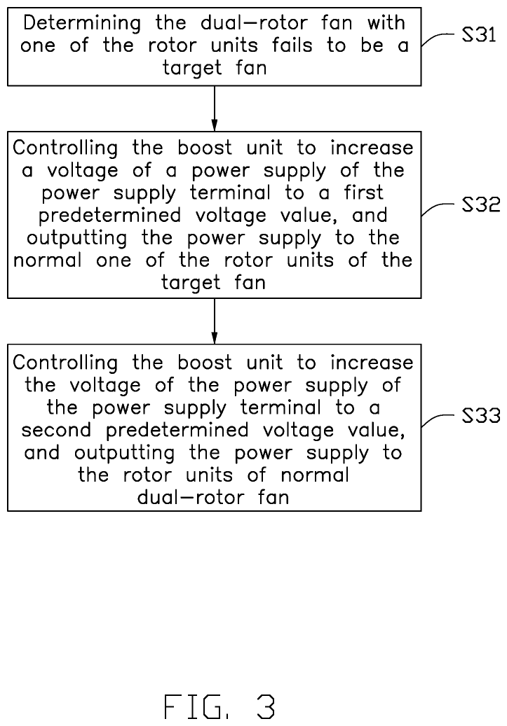

FIG. 3 illustrates another flow chat of at least one embodiment of a method for controlling fan. The method shown in FIG. 3 includes blocks S31, S32, and S33, of which blocks S31 and S32 are the same with blocks S21 and S22 as shown in FIG. 2, which are not repeated here. The method of FIG. 3 further includes:

At block S33, controlling the boost unit to increase the voltage of the power supply of the power supply terminal to a second predetermined voltage value, and outputting the power supply to the rotor units of normal dual-rotor fans.

In at least one embodiment, since the input voltage of the one normal rotor unit of the target fan is increased, the air flow generated by the target fan still may not fully prevent heat accumulation in corresponding areas of the computer equipment. Thus, for preventing heat accumulation in corresponding areas of the computer equipment, controlling the boost unit to increase the voltage of the power supply of the power supply terminal to the second predetermined voltage value, and outputting the power supply to the rotor units of normal dual-rotor fans, to increase the working speed of the rotor units of normal dual-rotor fans, so as to ensure heat accumulation in corresponding areas of the computer equipment being further prevented.

The first predetermined voltage value is greater than the second predetermined voltage value. Each of the first predetermined voltage value and the second predetermined voltage value is greater than the voltage of the power supply provided to the dual-rotor fan. That is, when increasing the working speed of the rotor units of normal dual-rotor fan, ensuring the working speed is not greater than the working speed of the normal one of the rotor units of the dual-rotor fan, so air flow for dissipating heat is generated and low power energy is costed.

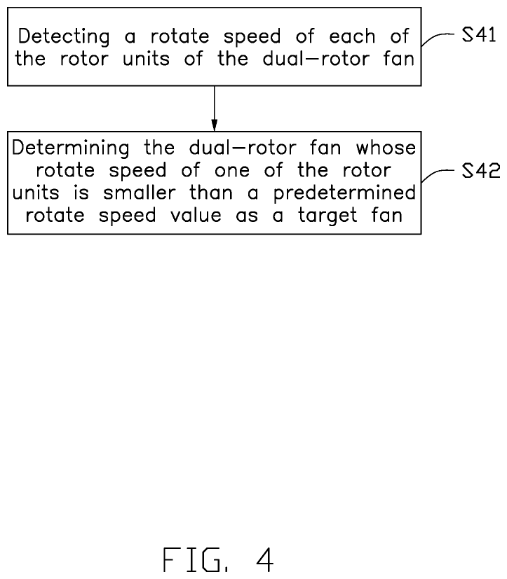

FIG. 4 illustrates a flow chat of at least one embodiment of a method for determined target fan. The method includes:

At block S41, detecting a rotate speed of each of the rotor units of the dual-rotor fans.

In at least one embodiment, the controlling system of the computer equipment or the heat dissipation device may obtain a rotate speed of each of the rotor units of the dual-rotor fans in real time. In detail, the controlling system of the computer equipment or the heat dissipation device may obtain the rotate speed of each of the rotor units of the dual-rotor fans in real time through a baseboard management controller of the dual-rotor fans.

At block S42, determining the dual-rotor fan whose rotate speed of one of the rotor units is smaller than a predetermined rotate speed value as the target fan.

After obtaining a present rotate speed of each of the rotor units of the dual-rotor fans in real time, the controlling system of the computer equipment or the heat dissipation device may compare the present rotate speed to the predetermined rotate speed value, and determine the rotor unit whose rotate speed is smaller than the predetermined rotate speed value as a failed rotor unit, and the dual-rotor fan corresponding to the failed rotor unit as the target fan.

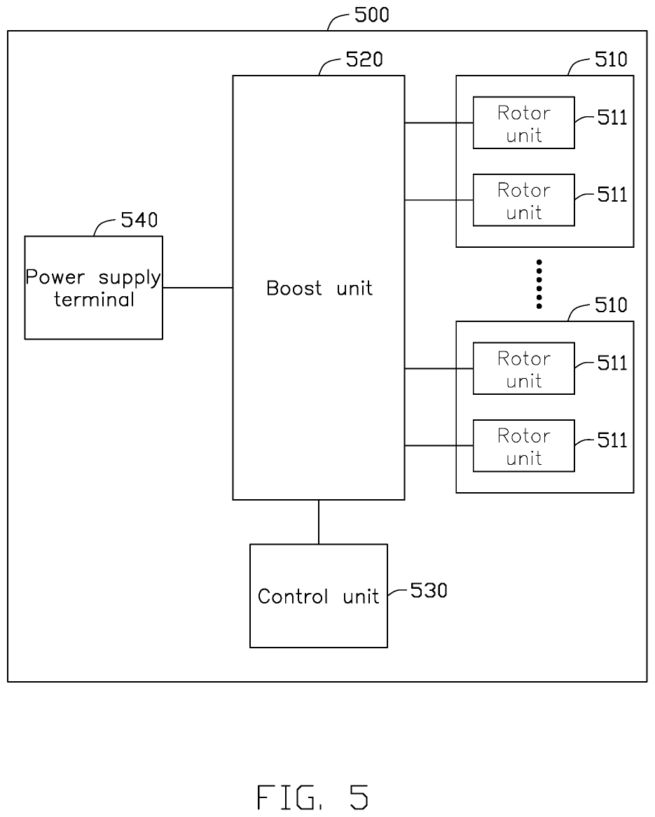

FIG. 5 illustrates a schematic diagram of at least one embodiment of a first kind of a heat dissipation device 500. The heat dissipation device 500 includes a plurality of dual-rotor fans 510. Each dual-rotor fan 510 includes two rotor units 511, a boost unit 520, and a control unit 530.

A first end of the boost unit 520 is connected to the rotor units 511 of the plurality of dual-rotor fans 510, a second end of the boost unit 520 is connected to a power supply terminal 540. The control unit 530 is connected to the boost unit 520, and further connected to the plurality of dual-rotor fans 510 through the boost unit 520.

The control unit 530 is configured to determine the dual-rotor fans 510 with one of the rotor units 511 fails to be a target fan; control the boost unit 520 to increase a voltage of a power supply of the power supply terminal 540 to a first predetermined voltage value, and output the power supply to the normal one of the rotor units 511 of the target fan 510.

The control unit 530 is further configured to control the boost unit 520 to increase the voltage of the power supply of the power supply terminal 540 to a second predetermined voltage value, and output the power supply to the rotor units 511 of normal dual-rotor fan 510.

In at least one embodiments of the present disclosure, for more detailed functional descriptions of the above-mentioned devices and units, reference may be made to the contents of corresponding parts in the foregoing embodiments, and details are not repeated here.

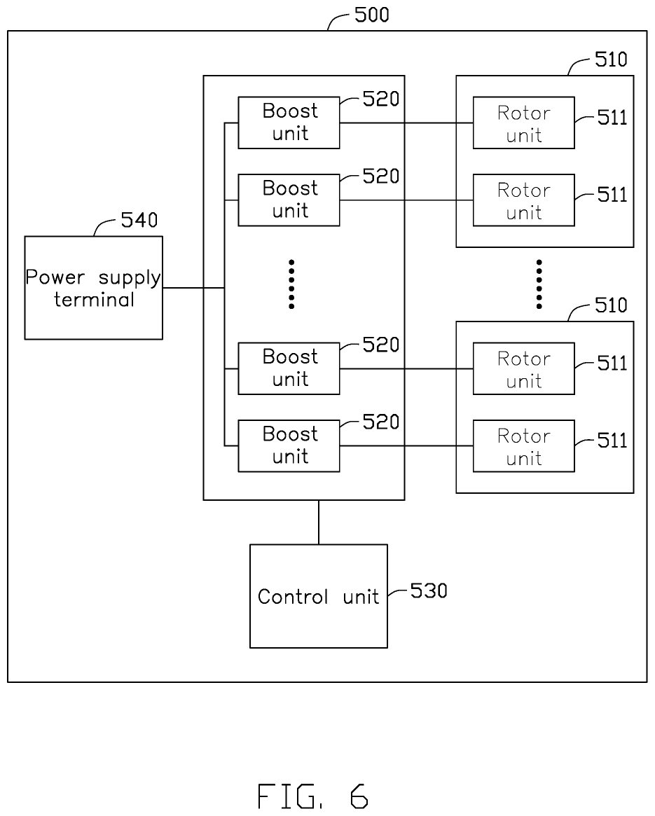

FIG. 6 illustrates a schematic diagram of at least one embodiment of a second kind of the heat dissipation device 500. The heat dissipation device 500 includes a plurality of dual-rotor fans 510. Each dual-rotor fan 510 includes two rotor units 511, the boost unit 520, and the control unit 530. Comparing the heat dissipation device 500 shown in FIG. 6 and the heat dissipation device 500 shown in FIG. 5, a difference may include:

The heat dissipation device 500 includes a plurality of boost units 520, a first end of each boost unit 520 is connected to a corresponding rotor unit 511 of the plurality of dual-rotor fans 510, a second end of each boost unit 520 is connected to the power supply terminal 540. That is, each rotor unit 511 of the plurality of dual-rotor fans 510 is connected to the power supply terminal 540 through one corresponding boost units 520, so the control unit 530 may individually control the input voltage of each rotor unit 511, which is convenient for more heat dissipation scenes.

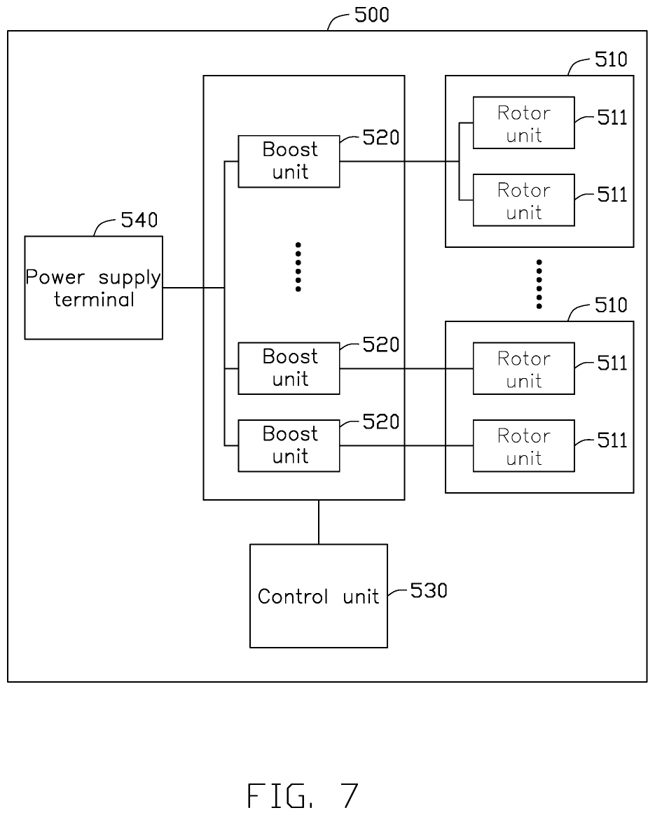

FIG. 7 illustrates a schematic diagram of at least one embodiment of a third kind of the heat dissipation device 500. The heat dissipation device 500 includes a plurality of dual-rotor fans 510. Each dual-rotor fan 510 includes two rotor units 511, the boost unit 520, and the control unit 530. Comparing the heat dissipation device 500 shown in FIG. 7 and the heat dissipation device 500 shown in FIG. 5, a difference may include:

The heat dissipation device 500 includes N boost units 520 and M rotor units 511, a first end of each boost unit 520 is connected to at least one rotor unit 511 of the plurality of dual-rotor fans 510, a second end of each boost unit 520 is connected to the power supply terminal 540. Wherein, each of N and M is a positive integer, and N is smaller than M. That is, according to heat dissipation demands, a quantity of the boost units 520 is flexibly adjustable, one boost unit 520 may be connected to a plurality of rotor units 511, and each boost unit 520 may be connected to different number of rotor units 511. The plurality of rotor units 511 connected to a same boost unit 520 may receive a same input voltage, which is convenient for management of corresponding heat dissipation areas of the computer equipment.

A non-transitory computer-readable storage medium including program instructions for causing the apparatus to perform the method for controlling fan is also disclosed.

An apparatus for controlling fan is also disclosed, the apparatus includes at least one processor and at least one memory, the at least one memory is coupled to the at least one processor and stores program instructions; the at least one memory and the program instructions is configured to, with the at least one processor, cause the apparatus to perform the method for controlling fan.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

What is claimed is:

1. A method of controlling fan applied in a heat dissipation device, the heat dissipation device comprising a plurality of dual-rotor fans, each of the plurality of dual-rotor fans comprising two rotor units and a boost unit, a first end of the boost unit being connected to the rotor units of the plurality of dual-rotor fans, a second end of the boost unit being connected to a power supply terminal; the method comprising:
determining if the dual-rotor fan with one of the rotor units fails to be a target fan;
controlling the boost unit to increase a voltage of a power supply of the power supply terminal to a first predetermined voltage value, and outputting the power supply to a normal one of the rotor units of the target fan.

2. The method of claim 1, further comprising:
controlling the boost unit to increase the voltage of the power supply of the power supply terminal to a second predetermined voltage value, and outputting the power supply to the rotor units of normal dual-rotor fans.

3. The method of claim 2, wherein the first predetermined voltage value is greater than the second predetermined voltage value.

4. The method of claim 1, wherein the determining the dual-rotor fan with one of the rotor units fails to be the target fan further comprises:
detecting a rotate speed of each of the rotor units of the plurality of dual-rotor fans; and
determining the dual-rotor fan whose rotate speed of one of the rotor units is smaller than a predetermined rotate speed value as the target fan.

5. The method of claim 1, further comprising:
controlling the boost unit to switch off the connection between the rotor units of the plurality of dual-rotor fans and the power supply terminal.

6. The method of claim 1, wherein the heat dissipation device comprises a plurality of boost units, a first end of each of the plurality of boost units is connected to a corresponding rotor unit of the plurality of dual-rotor fans, a second end of each of the plurality of boost units is connected to the power supply terminal.

7. The method of claim 1, wherein the heat dissipation device comprises N boost units and M rotor units, a first end of each of the N boost units is connected to at least one of the M rotor units of the plurality of dual-rotor fans, a second end of each of the N boost units is connected to the power supply terminal, each of N and M is a positive integer, and N is smaller than M.

8. The method of claim 1, wherein the boost unit is arranged on a first cable that connected between the rotor units of the plurality of dual-rotor fans and the power supply terminal;
when the rotor units of the plurality of dual-rotor fans work normally, the boost unit is configured to conduct the power supply;
when one of the rotor units of the plurality of dual-rotor fans fails, the boost unit starts and increases the voltage that transmitted from the first cable to the rotor units to the first predetermined voltage value, to increase a working speed of the rest of the rotor units of the plurality of dual-rotor fans.

9. The method of claim 8, wherein the boost unit is arranged on a second cable that connected between the rotor units of the plurality of dual-rotor fans and the power supply terminal;
when the rotor units of the plurality of dual-rotor fans work normally, the boost unit is configured to switch off the connection between the rotor units of the plurality of dual-rotor fans and the power supply terminal by the second cable, the rotor units of the plurality of dual-rotor fans receive the power supply from the power supply terminal through the first cable;
when one of the rotor units of the plurality of dual-rotor fans fails, the first cable is switched off, the boost unit starts and increases the voltage that transmitted from the second cable to the rotor units to the first predetermined voltage value, to increase the working speed of the rest of the rotor units of the dual-rotor fans.

10. The method of claim 1, wherein the boost unit comprises a charge pump and a boost circuit for increasing voltages.

11. A heat dissipation device comprising:
a plurality of dual-rotor fans, each of the plurality of dual-rotor fans comprising two rotor units;
a boost unit, a first end of the boost unit connected to the rotor units of the plurality of dual-rotor fans, a second end of the boost unit connected to a power supply terminal; and
a control unit, the control unit connected to the boost unit, the control unit connected to the plurality of dual-rotor fans through the boost unit, the control unit is configured to:
determine if the dual-rotor fan with one of the rotor units fails to be a target fan;
control the boost unit to increase a voltage of a power supply of the power supply terminal to a first predetermined voltage value, to output the power supply to a normal one of the rotor units of the target fan.

12. The heat dissipation device of claim 11, wherein the control unit is further configured to controlling the boost unit to increase the voltage of the power supply of the power supply terminal to a second predetermined voltage value, to output the power supply to the rotor units of normal dual-rotor fans.

13. The heat dissipation device of claim 12, wherein the first predetermined voltage value is greater than the second predetermined voltage value.

14. The heat dissipation device of claim 11, wherein the control unit is further configured to:
detect a rotate speed of each of the rotor units of the plurality of dual-rotor fans; and
determine the dual-rotor fan whose rotate speed of one of the rotor units is smaller than a predetermined rotate speed value as the target fan.

15. The heat dissipation device of claim 11, wherein the control unit is further configured to control the boost unit to switch off the connection between the rotor units of the plurality of dual-rotor fans and the power supply terminal.

16. The heat dissipation device of claim 11, wherein the heat dissipation device comprises a plurality of boost units, a first end of each of the plurality of boost units is connected to a corresponding rotor unit of the plurality of dual-rotor fans, a second end of each of the plurality of boost units is connected to the power supply terminal.

17. The heat dissipation device of claim 11, wherein the heat dissipation device comprises N boost units and M rotor units, a first end of each of the N boost units is connected to at least one of the M rotor units of the plurality of dual-rotor fans, a second end of each of the N boost units is connected to the power supply terminal, each of N and M is a positive integer, and N is smaller than M.

18. The heat dissipation device of claim 11, wherein the boost unit is arranged on a first cable that connected between the rotor units of the plurality of dual-rotor fans and the power supply terminal;
when the rotor units of the plurality of dual-rotor fans work normally, the boost unit is configured to conduct the power supply;
when one of the rotor units of the plurality of dual-rotor fans fails, the boost unit starts and increases the voltage that transmitted from the first cable to the rotor units to the first predetermined voltage value, to increase a working speed of the rest of the rotor units of the plurality of dual-rotor fans.

19. The heat dissipation device of claim 18, wherein the boost unit is arranged on a second cable that connected between the rotor units of the plurality of dual-rotor fans and the power supply terminal;
when the rotor units of the plurality of dual-rotor fans work normally, the boost unit is configured to switch off the connection between the rotor units of the plurality of dual-rotor fans and the power supply terminal by the second cable, the rotor units of the plurality of dual-rotor fans receive the power supply from the power supply terminal through the first cable;
when one of the rotor units of the plurality of dual-rotor fans fails, the first cable is switched off, the boost unit starts and increases the voltage that transmitted from the second cable to the rotor units to the first predetermined voltage value, to increase the working speed of the rest of the rotor units of the dual-rotor fans.

20. The heat dissipation device of claim 11, wherein the boost unit comprises a charge pump and a boost circuit for increasing voltages.
